(19) United States
(12) Patent Application Publication
(10) Pub. No.: US 2026/0304989 A1
(43) Pub. Date: Oct. 1, 2026

(54) IMAGE SENSING DEVICE

(71) Applicant: SK hynix Inc., Icheon-si (KR)

(72) Inventor: Woo Yung JUNG, Icheon-si (KR)

(21) Appl. No.: 19/380,765

(22) Filed: Nov. 5, 2025

(30) Foreign Application Priority Data
Mar. 31, 2025 (KR) 10-2025-0041185

(51) Int. Cl. H10F 39/00

(52) U.S. Cl. CPC H10F 39/807; H10F 39/8053

(57) ABSTRACT

An image sensing device includes a semiconductor substrate; an image pixel region supported by the semiconductor substrate; a first dummy pixel region supported by the semiconductor substrate and located outside the image pixel region; a second dummy pixel region supported by the semiconductor substrate and located outside the first dummy pixel region; a plurality of color filters disposed over the semiconductor substrate; and a grid structure disposed between the plurality of color filters. The grid structure includes: a first grid structure disposed with in the image pixel region and the first dummy pixel region and continuously connected in a first direction and a second direction intersecting the first direction; and a second grid structure disposed within the second dummy pixel region and continuously connected in the first direction and the second direction. The first grid structure and the second grid structure are isolated from each other.

### CROSS-REFERENCE TO RELATED APPLICATION

This patent document claims the priority and benefits of Korean patent application No. 10-2025-0041185, filed on Mar. 31, 2025, which is incorporated by reference in its entirety as part of the disclosure of this patent document.

### TECHNICAL FIELD

The technology and implementations disclosed in this patent document generally relate to an image sensing device.

### BACKGROUND

An image sensor is used to capture optical images by converting light into electrical signals using a photosensitive semiconductor material which reacts to light. With the recent development of automotive, medical, computer and communication industries, the demand for high-performance image sensors is increasing in various fields such as smartphones, digital cameras, camcorders, personal communication systems (PCSs), game consoles, IoT (Internet of Things), robots, surveillance cameras, medical micro cameras, etc.

### SUMMARY

Various embodiments of the disclosed technology relate to an image sensing device that prevents foreign substances from penetrating into an air layer of an effective pixel region within a grid structure including the air layer.

In accordance with an embodiment of the disclosed technology, an image sensing device may include a semiconductor substrate; an image pixel region supported by the semiconductor substrate; a first dummy pixel region supported by the semiconductor substrate and located outside the image pixel region; a second dummy pixel region supported by the semiconductor substrate and located outside the first dummy pixel region and the image pixel region; a plurality of color filters disposed over the semiconductor substrate to correspond to pixels of the image pixel region, pixels of the first dummy pixel region and pixels of the second dummy pixel region; and a grid structure disposed between the plurality of color filters. The grid structure may include: a first grid structure disposed within the image pixel region and the first dummy pixel region and continuously connected in a first direction and a second direction intersecting the first direction; and a second grid structure disposed within the second dummy pixel region and continuously connected in the first direction and the second direction. The first grid structure and the second grid structure may be isolated from each other.

In accordance with another embodiment of the disclosed technology, an image sensing device may include a semiconductor substrate including a first region and a second region surrounding the first region; a plurality of color filters disposed over the semiconductor substrate; and at least one grid structure disposed between adjacent color filters of the plurality of color filters, wherein the at least one grid structure includes a first grid structure in the first region and a second grid structure in the second region, and the first grid structure of the first region and the second grid structure of the second region are disconnected from each other.

In accordance with another embodiment of the disclosed technology, an image sensing device may include: a semiconductor substrate including a first region and a second region surrounding the first region; a plurality of color filters disposed over the semiconductor substrate; and a grid structure disposed between the plurality of color filters and configured to include an air layer and a capping layer surrounding the air layer, wherein the grid structure is configured such that a layer thickness of the capping layer gradually becomes thicker in a direction closer to an edge region of the second region.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some embodiments of the disclosed technology.

FIG. 2 is a plan view illustrating an example of appearance of a grid structure formed in some portions of a pixel region shown in FIG. 1 based on some implementations of the disclosed technology.

FIG. 3A is a cross-sectional view illustrating an example of the grid structure taken along the line X1-X1’ shown in FIG. 2 based on some embodiments of the disclosed technology.

FIG. 3B is a cross-sectional view illustrating an example of the grid structure taken along the line X2-X2’ shown in FIG. 2 based on some embodiments of the disclosed technology.

FIGS. 4-12 are cross-sectional views illustrating examples of a method for forming the grid structure shown in FIG. 3A based on some embodiments of the disclosed technology.

FIG. 13 is a cross-sectional view illustrating an example of the grid structure based on some embodiments of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device that prevents foreign substances from penetrating into an air layer of an effective pixel region within a grid structure including the air layer. In recognition of the issues above, the disclosed technology provides various implementations of the image sensing device that prevents foreign substances from penetrating into the air layer of the effective pixel region within the grid structure including the air layer.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

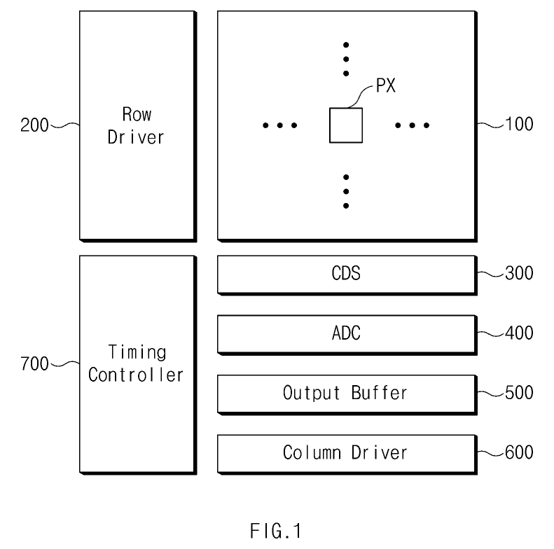

FIG. 1 is a block diagram illustrating an example of an image sensing device according to embodiments of the disclosed technology.

Referring to FIG. 1, the image sensing device may include a pixel region100, a row driver 200, a correlated double sampler (CDS) 300, an analog-to-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel region 100 may include a plurality of unit pixels (PXs) consecutively arranged in a two-dimensional (2D) structure. The unit pixels (PXs) may convert incident light into electrical signals corresponding to the incident light, and may generate pixel signals. The pixel region 100 may include a grid structure to prevent crosstalk between color filters of adjacent unit pixels. The grid structure may include an air layer. A grid structure formed in each of an effective pixel region (image pixel region) and a first dummy pixel region adjacent to the effective pixel region and a grid structure formed in a second dummy pixel region located outside the first dummy pixel region may be isolated from each other.

The row driver 200 may select one or more unit pixels connected to at least one row line of the pixel region 100 based on control signals received from a control circuit such as the timing controller.

The correlated double sampler (CDS) 300 may remove undesired offset values of the unit pixels using correlated double sampling.

The ADC 400 may convert the CDS signal received from the correlated double sampler (CDS) 300 into a digital signal.

The output buffer 500 may temporarily store column-based data received from the ADC 400 under the control of the timing controller 700.

The column driver 600 may select a column of the output buffer 500 under the control of the timing controller 700, and may sequentially output data temporarily stored in the selected column of the output buffer 500.

The timing controller 700 may generate signals for controlling operations of the row driver 200, the ADC 400, the output buffer 500 and the column driver 600.

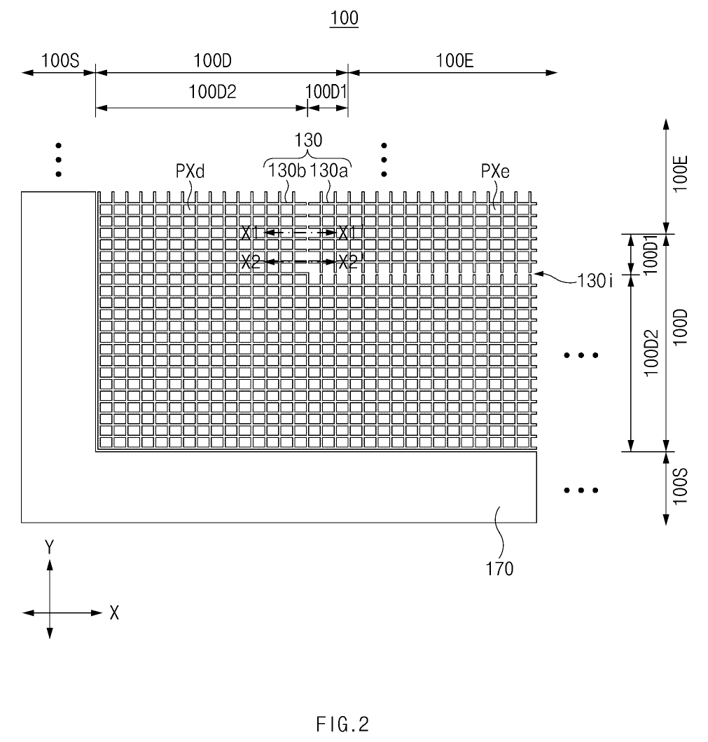

FIG. 2 is a plan view illustrating an example of appearance of the grid structure formed in the pixel region 100 shown in FIG. 1 based on some implementations of the disclosed technology.

Referring to FIG. 2, the pixel region 100 may include an image or effective pixel region 100E with pixels that detect incident light for capturing images in the incident light and a dummy pixel region 100D with pixels that are not used for capturing images in the incident light.

The image or effective pixel region 100E may be formed at the center of the pixel region 100 to include an array of effective pixels (PXe) included to capture an image projected onto the image sensing device, for example, by sensing incident light and converting the sensed incident light into photocharges which are used to produce electrical signals for the PXe. The dummy pixel region 100D may be located outside the effective pixel region 100E while being adjacent to the effective pixel region 100E. The dummy pixel region 100D includes dummy pixels (PXd) that are similarly constructed as the imaging or effective pixels (PXe) in the effective pixel region 100E. For example, the effective pixel region 100E may be formed in a square shape and the dummy pixel region 100D may be formed in a square frame shape surrounding the effective pixel region 100E.

The effective pixel region 100E may include effective pixels (PXe) that are arranged consecutively in a first direction (e.g., X-axis direction) and a second direction (e.g., Y-axis direction) perpendicular to the first direction. Effective pixels (PXe) may refer to pixels for image generation by producing photocharges in response to received incident light to represent the image information of the image carried by the incident light.

The dummy pixel region 100D may include dummy pixels (PXd) arranged consecutively in the first direction and the second direction. The dummy pixels (PXd) may have the same or similar structure as the effective pixels (PXe), while not being used for image generation. For example, the dummy pixels region 100D may include pixels for test, and may help to solve the problems caused by a step difference that is generated between the effective pixel region 100E and the shielding region 100S by a light absorption layer 170 formed in the shielding region 100S.

The effective pixels (PXe) and the dummy pixels (PXd) may include color filters. The pixel region 100 may include a grid structure 130 disposed between adjacent color filters of the adjacent pixels to prevent optical crosstalk between the adjacent color filters.

The grid structure 130 may include a plurality of first portions extending across the effective pixel region 100E and the dummy pixel region 100D in a first direction between the color filters, and a plurality of second portions extending across the effective pixel region 100E and the dummy pixel region 100D in a second direction between the color filters. The first portions and the second portions may be formed to cross each other and surround each of the color filters. For example, the color filters may be formed in a region defined by the plurality of first portions and the plurality of second portions.

The grid structure 130 may be an air grid including an air layer and a capping layer covering the air layer. The capping layer may include a multilayer structure in which a plurality of insulation layers is formed to overlap each other. For example, the capping layer may include a first capping layer including a through-hole and a second capping layer that fills the through-hole and is formed on an inner surface and an outer surface of the first capping layer. The capping layer may include an ultra-low-temperature oxide (ULTO) layer such as a silicon oxide (SiO₂) layer.

The grid structure 130 formed in the dummy pixel region 100D may be separated into two regions by a grid isolation region 130i. For example, the dummy pixel region 100D may include a first dummy pixel region 100D1 located outside the effective pixel region 100E while being adjacent to the effective pixel region 100E, and a second dummy pixel region 100D2 located outside the first dummy pixel region 100D1 while being adjacent to the first dummy pixel region 100D1. The first grid structure 130a may be formed in the effective pixel region 100E and the first dummy pixel region 100D1 and the second grid structure 130b may be formed in the second dummy pixel region 100D2 only without being disposed in the effective pixel region 100E. The first grid structure 130a and the second grid structure 130b may be isolated from each other by the grid isolation region 130i. Thus, the first grid structure 130a and the second grid structure 130b may be disconnected or separated from each other without being continuously connected to each other. For example, the air layers of the first grid structure 130a within the effective pixel region 100E and the first dummy pixel region 100D1 may be connected to each other, and the air layers of the second grid structure 130b may also be connected to each other within the second dummy pixel region 100D2. In the implementations, the air layers of the first grid structure 130a and the air layers of the second grid structure 130b may not be connected to each other and may be isolated from each other.

In the grid isolation region 130i, the grid structure 130 is not formed. The grid isolation region 130i may be distinguished from other regions where the grid structure 130 is formed. In the example, the grid isolation region 130i may be formed in a square band shape surrounding the first grid structure 130a. Although FIG. 2 illustrates the grid isolation region 130i formed in a shape in which one line of the grid structure is removed in each of the first direction and the second direction for convenience of description, other implementations are also possible, and the grid isolation region 130i may also be formed in a shape in which multiple lines of the grid structure are removed in each of the first direction and the second direction.

Although the grid isolation region 130i is illustrated in FIG. 2 in a form in which the grid structure of one line is removed in each of the first direction and the second direction, the grid structure of the plurality of lines may be removed in the first direction and the second direction, respectively.

A shielding region 100S may be disposed outside the dummy pixel region 100D to prevent incident light from entering the substrate. The shielding region 100S may include a light absorption layer 170 for absorbing the incident light. The light absorption layer 170 may include a metal (e.g., tungsten) and may be formed on the substrate. For example, the shielding region 100S may include optical black pixel region.

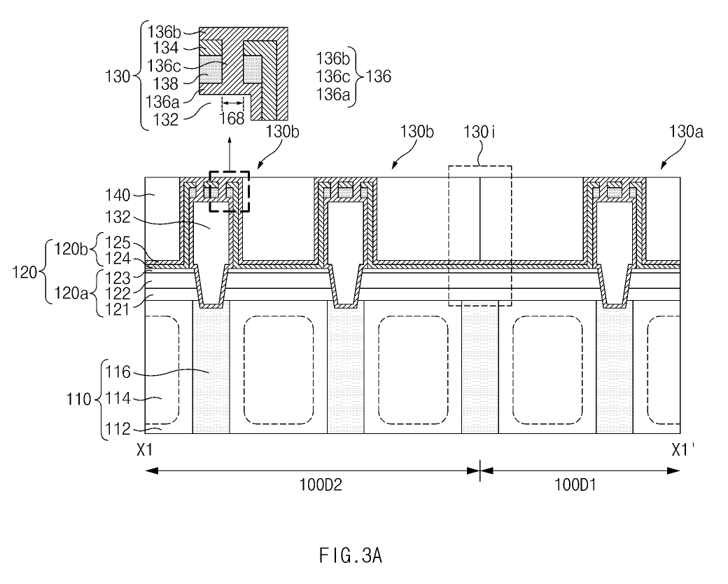

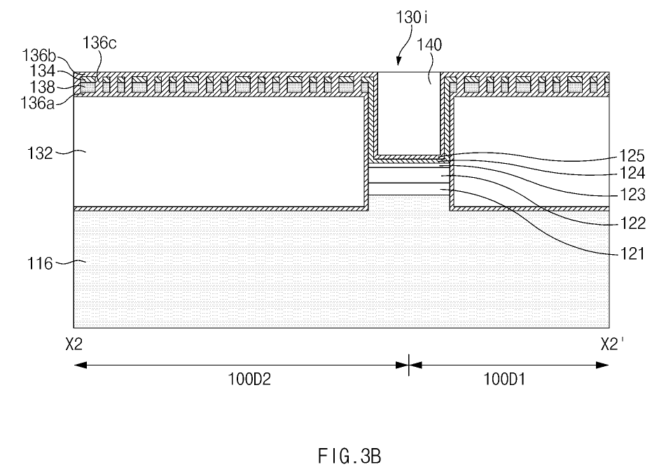

FIG. 3A is a cross-sectional view illustrating an example of the grid structure taken along the line X1-X1’ shown in FIG. 2 based on some embodiments of the disclosed technology. FIG. 3B is a cross-sectional view illustrating an example of the grid structure taken along the line X2-X2’ shown in FIG. 2 based on some embodiments of the disclosed technology.

Referring to FIGS. 3A and 3B, the pixel region 100 of the image sensing device may include a substrate layer 110, a buffer layer 120, a grid structure 130, and a plurality of color filters 140.

The substrate layer 110 may include a substrate 112, photoelectric conversion elements 114, and a pixel isolation structure 116.

The substrate 112 may include a semiconductor substrate having a first surface and a second surface facing or opposite to the first surface. In the example, the first surface is a surface upon which light is incident, and the buffer layer 120, the grid structure 130, and the color filters 140 may be formed thereon. The semiconductor substrate 112 may be in a monocrystalline state, and may include a silicon-containing material. In some implementations, the semiconductor substrate 112 may include a monocrystalline silicon-containing material. The semiconductor substrate 112 may include P-type impurities. The semiconductor substrate 112 may include photoelectric conversion elements 114 and the pixel isolation structures 116.

The semiconductor substrate 112 may include an effective pixel region 100E in which the effective pixels (PXe) are formed, a first dummy pixel region 100D1 and a second dummy pixel region 100D2, each of which includes dummy pixels (PXd). Only the first dummy pixel region 100D1 and the second dummy pixel region 100D2 are illustrated in FIGS. 3A and 3B.

The photoelectric conversion elements 114 may perform conversion of incident light received through the first surface of the semiconductor substrate 112, resulting in generating photocharges. The photoelectric conversion elements 114 may be formed in the semiconductor substrate 112 to respectively correspond to the effective pixels (PXe) and the dummy pixels (PXd). The photoelectric conversion elements 114 may be isolated from each other by the pixel isolation structure 116. In the example, the photoelectric conversion elements 114 may include N-type impurity regions.

The pixel isolation structure 116 may be formed between adjacent photoelectric conversion elements 114 within the semiconductor substrate 112 so that the photoelectric conversion elements 114 can be isolated from each other for each pixel to avoid crosstalk in the generated photocharges separately generated by the adjacent photoelectric conversion elements 114. In some implementations, the pixel isolation structure 116 may include a trench structure such as Back Deep Trench Isolation (BDTI) or Front Deep Trench Isolation (FDTI). Alternatively, the pixel isolation structure 116 may include a junction isolation structure in which a high concentration of impurities (e.g., P-type impurities) is implanted into the semiconductor substrate 112.

The buffer layer 120 may be disposed between the semiconductor substrate 112 and the color filters 140 over the first surface of the substrate layer 110. The buffer layer 120 may operate as a planarization layer to remove a step difference formed over the first surface of the substrate layer 110. In addition, the buffer layer 120 may operate as an anti-reflection layer to allow incident light to pass through the photoelectric conversion elements 114.

The buffer layer 120 may include a multilayer structure formed by stacking an oxide layer and a nitride layer. For example, the buffer layer 120 may include a lower buffer layer 120a and an upper buffer layer 120b.

The lower buffer layer 120a may be formed on the substrate layer 110 so as to contact the substrate layer 110. The lower buffer layer 120a may include first to third buffer layers (121, 122, 123). The first buffer layer 121 may include a metal oxide layer such as aluminum oxide (Al₂O₃) or hafnium oxide (HfO₂). The second buffer layer 122 may include a silicon oxide (SiO₂) layer, and the third buffer layer 123 may include a nitride layer such as a silicon nitride layer or a silicon oxynitride layer.

The upper buffer layer 120b may be disposed between the lower buffer layer 120a and the color filters 140. The upper buffer layer 120b may include a fourth buffer layer 124 and a fifth buffer layer 125. The fourth buffer layer 124 may be formed of the same material as the first capping layer 134 of the grid structure 130, and may be formed together with the first capping layer 134 through the same deposition process. The fifth buffer layer 125 may be formed of the same material as the second capping layer 136 of the grid structure 130, and may be formed together with the second capping layer 136 through the same deposition process. For example, the fourth buffer layer 124 and the fifth buffer layer 125 may be formed such that the first capping layer 134 and the second capping layer 136 extend below the color filter 140. The fourth buffer layer 124 and the fifth buffer layer 125 may include an ultra-low-temperature oxide (ULTO) layer.

The grid structure 130 may be disposed between the color filters 140 to prevent optical crosstalk between adjacent color filters. The grid structure 130 may be formed on or over the pixel isolation structure to overlap the pixel isolation structure 116 which is to isolate adjacent photoelectric conversion elements 114 below their respective color filters. For example, the grid structure 130 may extend in a vertical direction (i.e., a depth direction) such that a bottom surface of the grid structure 130 is in contact with the pixel isolation structure 116. In some implementations, the grid structure 130 may include an air layer 132, a first capping layer 134, a second capping layer 136, and a support layer 138.

The air layer 132 including air may be formed in a region defined by the first capping layer 134 and the second capping layer 136. The air layer 132 may extend downward to a preset depth that penetrates the lower buffer layer 120a. As described above, since the air layer 132 is formed to extend deeply, the incident light may be prevented from causing crosstalk with the lower buffer layer 120a.

The first capping layer 134 and the second capping layer 136 may cap (or cover) the air layer 132. For example, the first capping layer 134 and the second capping layer 136 may define a region where the air layer 132 is formed. The first capping layer 134 may be disposed in the second capping layer 136. For example, the first capping layer 134 and the second capping layer 136 may be formed in a structure in which the second capping layer 136 is deposited on the inner surface and the outer surface of the first capping layer 134 to entirely surround the first capping layer 134.

The upper region of the first capping layer 134 may be penetrated by first holes 168. The first holes 168 may be formed using a direct self-assembly process of a block copolymer.

The second capping layer 136 may include an inner capping layer 136a, an outer capping layer 136b, and a buried capping layer 136c. The inner capping layer 136a may be formed to cover the inner surface of the first capping layer 134. The inner capping layer 136a may be formed to contact the air layer 132. The inner capping layer 136a may extend downward to a preset depth that penetrates the lower buffer layer 120a.

The outer capping layer 136b may be formed to cover the outer surface of the first capping layer 134. The outer capping layer 136b may be located at the outermost portion of the grid structure 130.

The buried capping layer 136c may be a region that fills the first holes 168. The inner capping layer 136a and the outer capping layer 136b may be connected to each other through the buried capping layer 136c.

Although the present embodiment has disclosed that the second capping layer 136 is divided into several regions (136a~136c), other implementations are also possible, and it should be noted that the inner capping layer 136a, the outer capping layer 136b, and the buried capping layer 136c may be formed simultaneously through the same deposition process. For example, the inner capping layer 136a and the buried capping layer 136c may be a structure in which a material corresponding to the buried capping layer 136c and a material corresponding to the inner capping layer 136a are introduced into the grid structure 130 through the first holes 168 when the outer capping layer 136b is formed so that the introduced materials are deposited on the inner surface of the first capping layer 134 to fill the first holes 168.

The first capping layer 134 and the second capping layer 136 may include the same material layer. For example, each of the first capping layer 134 and the second capping layer 136 may include an ultra-low-temperature oxide (ULTO) layer. Alternatively, the first capping layer 134 may include an ultra-low-temperature oxide (ULTO) layer, and the second capping layer 136 may include a material layer different from that of the first capping layer 134. For example, the second capping layer 136 may include at least one of an aluminum oxide layer (Al₂O₃), a hafnium oxide layer (HfO₂), or a silicon nitride layer (SiN).

The support layer 138 may be disposed on the inner surface of the first capping layer 134 in the upper region of the grid structure 130. The support layer 138 may support the first capping layer 134 to prevent the first capping layer 134 from collapsing during the forming of the air layer 132. The support layer 138 may include an insulation layer having no light absorption characteristics. For example, the support layer 138 may be or include an insulation layer with a different etch selectivity from a spin on carbon (SOC) layer containing carbon, and may include a silicon oxynitride (SiON) layer. An upper region of the support layer 138 may also be penetrated by the first holes 168. The support layer 138 may not be formed as needed.

The grid isolation region 130i may be disposed within the dummy pixel region 100D. The grid structure 130 is not formed in the grid isolation region 130i. The grid isolation region 130i may overlap the pixel isolation structure 116. Whereas the air layer 132 of the first grid structure 130a within the first dummy pixel region 100D1 is integrally connected to each other, and the air layer 132 of the second grid structure 130b within the second dummy pixel region 100D2 is also integrally connected to each other, the air layer 132 of the first grid structure 130a and the air layer 132 of the second grid structure 130b may not be connected to each other. The air layer 132 of the first grid structure 130a and the air layer 132 of the second grid structure 130b may be isolated from each other by the grid isolation region 130i.

The color filters 140 may filter light incident through the lens layer 150 depending on colors of the incident light, and may allow the filtered light to pass therethrough. The color filters 140 may be disposed in a region defined by the grid structure 130 on the substrate layer 110. The color filters 140 may be located to correspond to the photoelectric conversion elements 114. The color filters 140 may include a plurality of red color filters, a plurality of green color filters, and a plurality of blue color filters.

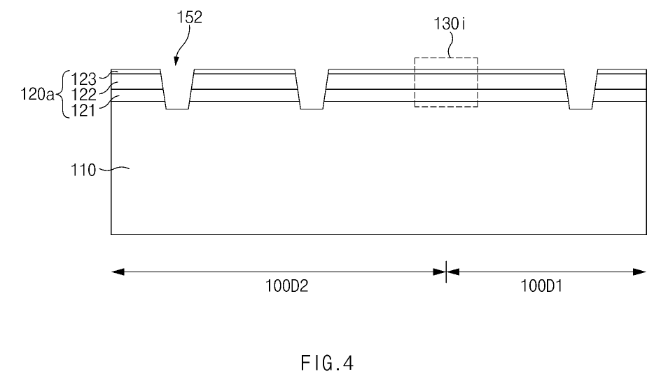

FIGS. 4 to 12 are cross-sectional views illustrating examples of a method for forming the grid structure shown in FIG. 3A based on some embodiments of the disclosed technology.

First, referring to FIG. 4, a lower buffer layer 120a may be formed over the substrate layer 110 in which the photoelectric conversion element and the pixel isolation structure are formed within the semiconductor substrate. For example, first to third buffer layers (121, 122, 123) may be sequentially formed over the substrate layer 110. At this time, the first buffer layer 121 may include a metal oxide layer such as an aluminum oxide layer (Al₂O₃) or a hafnium oxide layer (HfO₂). The second buffer layer 122 may include a silicon oxide layer (SiO₂), and the third buffer layer 123 may include a nitride layer such as a silicon nitride layer or a silicon oxide nitride layer.

Subsequently, a trench 152 in which a region where the grid structure 130 is to be formed in the lower buffer layer 120a is etched to a certain depth may be formed. For example, the trench 152 may penetrate the lower buffer layer 120a and may be formed to a preset depth such that the pixel isolation structure of the substrate layer 110 is exposed.

In this case, the trench 152 may not be formed in the grid isolation region 130i.

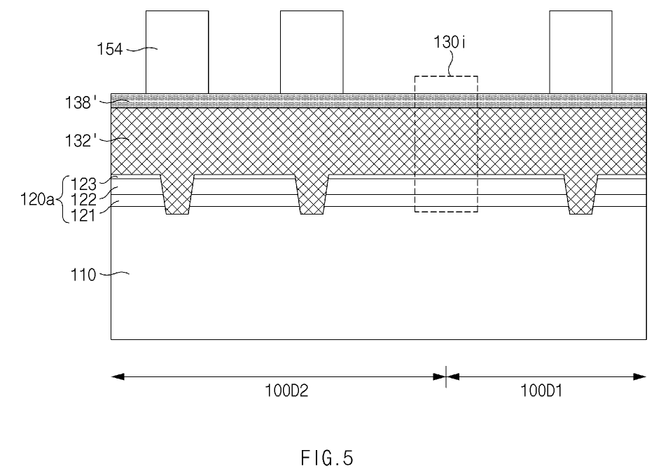

Referring to FIG. 5, a sacrificial layer 132’ may be formed over the lower buffer layer 120a in which the trench 152 is formed, and a support material layer 138’ may be formed over the sacrificial layer 132’. At this time, the sacrificial layer 132’ may include a SOC (Spin On Carbon) layer containing carbon, and the support material layer 138’ may include a silicon oxynitride layer (SiON).

Subsequently, a mask pattern 154 defining a region to be capped by the first capping layer 134 may be formed over the support material layer 138’. For example, a mask pattern 154 defining a region where the inner capping layer 136a and the air layer 132 of FIGS. 3A and 3B are to be formed may be formed over the support material layer 138’. The mask pattern 154 may include a photoresist pattern.

In this case, the mask pattern 154 may not be formed in the grid isolation region 130i.

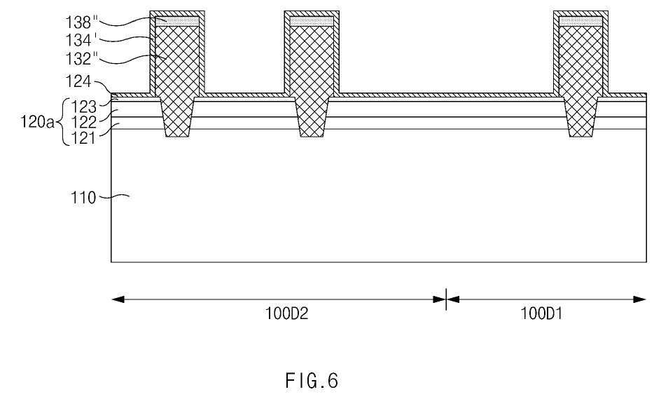

Referring to FIG. 6, the support material layer 138’ and the sacrificial layer 132’ may be sequentially etched using the mask pattern 154 as an etching mask, thereby forming a support layer pattern 138” and a sacrificial layer pattern 132”.

Subsequently, the insulation layers (124, 134’) may be formed to cover the lower buffer layer 120a, the sacrificial layer pattern 132”, and the support layer pattern 138”. The insulation layer (124, 134’) may include an ultra-low-temperature oxide (ULTO) layer. Although the present embodiment has disclosed that the insulation layers (124, 134’) are shown as different layers for convenience of description, the insulation layers (124, 134’) may be formed simultaneously through the same process.

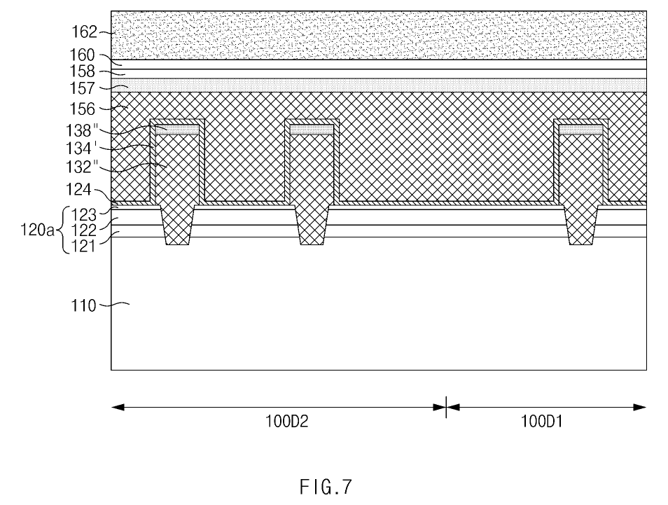

Referring to FIG. 7, insulation layers (156, 157, 158) may be sequentially formed on the insulation layers (124, 134’). At this time, the insulation layer 156 may include a carbon-containing SOC (Spin On Carbon) layer, and the insulation layer 157 may include a silicon oxide nitride layer (SiON). The insulation layer 158 may include a polysilicon layer.

Thereafter, a neutral layer 160 and a direct self-assembly (DSA) material layer 162 may be sequentially formed over the insulation layer 158.

The neutral layer 160 may induce pattern formation of the DSA material layer 162. The neutral layer 160 may serve to induce polymer blocks forming a block copolymer to be phase-separated into block domain portions that are alternately repeated in a cylindrical shape or a lamellar shape. The neutral layer 160 may operate as an orientation control layer that controls orientation of the polymer blocks during the phase separation process in which the polymer blocks are re-ordered to form block domain portions, thereby causing the block domain portions to be alternately repeated.

The neutral layer 160 may be formed of a material having a similar affinity for each of the polymer block components forming the block copolymer. For example, the neutral layer 160 may include a random copolymer in which different polymer components forming the block copolymer are randomly copolymerized. When a polystyrene-polymethyl methacrylate block copolymer (PS-b-PMMA) is used as a self-aligned block copolymer, the neutral layer 160 may include a random copolymer of polystyrene and polymethyl methacrylate (PS-b-PMMA) (i.e., random PS: PMMA (PS-r-PMMA)).

The DSA material layer 162 may include a block copolymer in which two or more types of polymer blocks having different structures are covalently bonded to form one polymer. For example, the DSA material layer 162 may include polymethyl methacrylate (PMMA) and polystyrene (PS). The DSA material layer 162 may be coated in a homogeneous phase mixed state using a spin coating method.

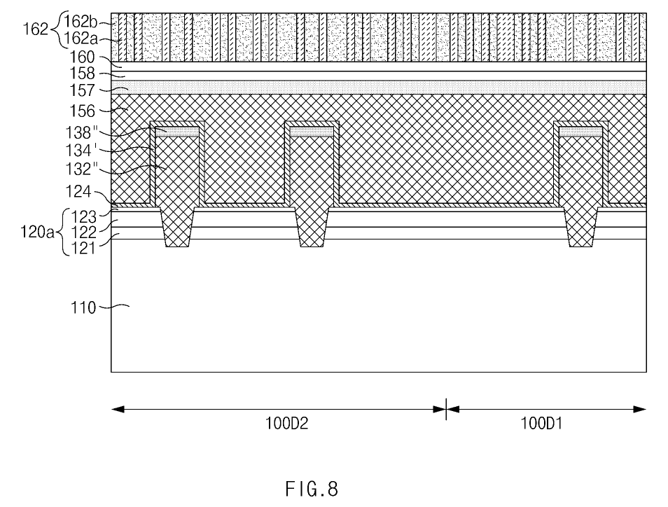

Referring to FIG. 8, DSA patterning may be performed on the DSA material layer 162. For example, an N₂ annealing process may be performed on the DSA material layer 162.

The DSA material layer 162 may be phase-separated into a first polymer block component 162a and a second polymer block component 162b by the annealing process. When the DSA material layer 162 includes a block copolymer, the DSA material layer 162 may be separated into PMMA (polymethylmethacrylate) and PS (polystyrene) by the annealing process. PMMA and PS may be self-aligned in various forms depending on a composition ratio.

The polymer block components that constitute the block copolymer may have different mixing characteristics and different solubilities due to differences in chemical structures. The polymer components may be immiscibly separated from each other while being intermixed by annealing, and may be reordered, so that the polymer components can be phase-separated from each other.

Forming a microstructure of a specific shape through direct self-assembly of the block copolymer may be affected by physical and/or chemical characteristics of each block polymer. When a block copolymer composed of two different polymers is self-assembled, the self-assembled structure of the block copolymer may be formed in various structures, such as a three-dimensional (3D) cubic and double helix structure, or a two-dimensional (2D) hexagonal packed column structure and a lamellar structure, depending on a volume ratio of each polymer block that constitutes the block copolymer, the annealing temperature for phase separation, the size of a molecule of the block polymer, and the like.

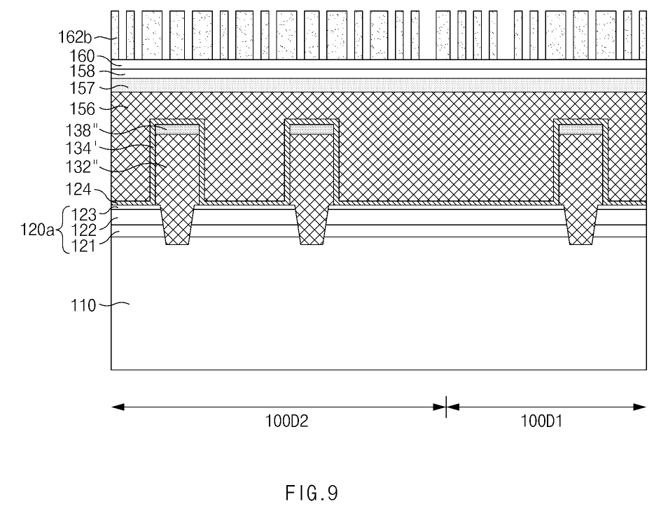

Referring to FIG. 9, the first polymer block component 162a may be selectively removed from the DSA material layer 162 separated into the first polymer block component 162a and the second polymer block component 162b.

For example, a metal-containing precursor may be injected into the DSA material layer 162 so that the metal-containing precursor can be selectively coupled (bound) to the first polymer block component 162a. The metal of the metal-containing precursor may include aluminum (Al). The metal-containing precursor may include tetramethylammonium (TMA). For example, TMA may be selectively coupled (bound) to PMMA.

By injecting such a metal-containing precursor, the metal may penetrate into the first polymer block component 162a, so that the first polymer block component 162a may be modified into the metal-containing first polymer block component. The metal-containing first polymer block component may have an etch selectivity with respect to the second polymer block component 162b. The first polymer block component 162a may be selectively removed using the etch selectivity.

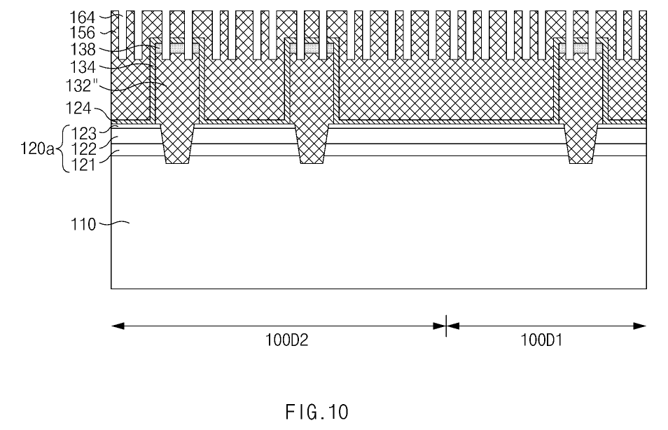

Referring to FIG. 10, a plurality of opening portions 164 may be formed by etching material layers (160, 158, 157, 156, 134’, 138”, 132”) using a DSA pattern including the second polymer block component 162b as an etch mask.

At this time, the plurality of openings 164 may expose the sacrificial layer pattern 132” capped by the insulation layer 134’ to the outside by penetrating the insulation layers (134’, 138”).

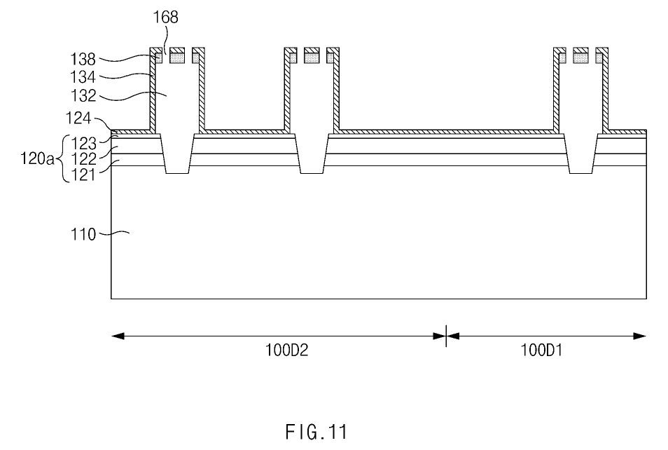

Subsequently, referring to FIG. 11, the insulation layer 156 and the sacrificial layer pattern 132” may be removed through the plasma process, so that the first capping layer 134 and the support layer 138 penetrated by the first holes 168 are formed, and the air layer 132 may be formed inside the first capping layer 134.

In some implementations, the plasma process may be carried out using gas (e.g., O₂, N₂, H₂, CO, CO₂, or CH₄) including at least one of oxygen, nitrogen, or hydrogen. For example, if the O₂ plasma process is carried out, oxygen radicals (O*) may flow into the insulation layer 156 and the sacrificial layer pattern 132”, and the oxygen radicals (O*) may be combined with carbons of the insulation layer 156 and the sacrificial layer pattern 132”. At this time, the sacrificial layer pattern 132” capped by the first capping layer 134 is exposed outside by the plurality of first holes 168 as shown in FIG. 10, so that the sacrificial layer pattern 132” may be coupled to the oxygen radicals. The oxygen radicals (O*) may be combined with carbons of the insulation layer 156 and the sacrificial layer pattern 132”, resulting in formation of CO or CO₂. As a result, the insulation layer 156 and the sacrificial layer pattern 132” can be removed. At this time, CO or CO₂ generated by the sacrificial layer pattern 132” located inside the first capping layer 134 may be discharged to the outside through the first holes 168, so that the CO or CO₂ can be removed.

When the plasma process is performed in a state where the sacrificial layer pattern 132” is completely capped, the oxygen radicals are introduced through the insulation layer 134’ and are combined with the sacrificial layer pattern 132”, and the generated gases must also escape to the outside through the insulation layer 134’, so that the sacrificial layer pattern 132” is not easily removed. However, as in the present embodiment, if the plasma process is performed with the sacrificial layer pattern 132” exposed to the outside, the sacrificial layer pattern 132” may be removed more easily, thereby securing a larger space in which the air layer 132 is formed.

The support layer 138 formed over the sacrificial layer pattern 132” may prevent the first capping layer 134 from collapsing by supporting the first capping layer 134 while the sacrificial layer pattern 132” is removed.

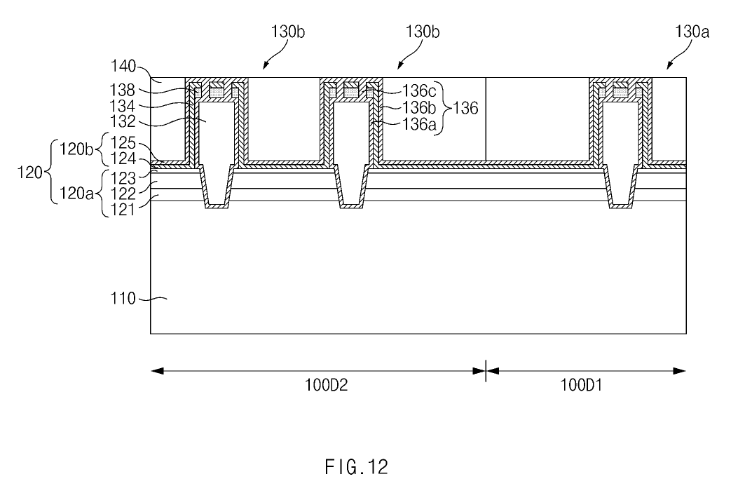

Referring to FIG. 12, the first grid structure 130a and the second grid structure 130b may be formed by depositing the insulation layer (e.g., an oxide layer) on the inner surface and the outer surface of the first capping layer 134 so that the first holes 168 can be filled with the insulation layer.

For example, an ultra-low-temperature oxide (ULTO) layer may be deposited on the inner and outer surfaces of the first capping layer 134 using an atomic layer deposition (ALD) process and/or a chemical vapor deposition (CVD) process, so that the inner capping layer 136a and the outer capping layer 136b of the second capping layer 136 can be formed. In the process of forming the inner capping layer 136a and the outer capping layer 136b, the inner portion of the first holes 168 is filled with the insulation layer, resulting in formation of the buried capping layer 136c. At this time, the insulation layer may be deposited over the fourth buffer layer 124 to form a fifth buffer layer 125.

The second capping layer 136 may be made of the same material (ULTO) as the first capping layer 134. Alternatively, the second capping layer 136 may be made of a different material from the first capping layer 134. For example, the second capping layer 136 may include an aluminum oxide layer (Al₂O₃), a hafnium oxide layer (HfO₂), or a silicon nitride layer (SiN).

Thereafter, color filters 140 may be formed in regions defined by the first grid structure 130a and the second grid structure 130b.

In addition, an overcoating layer (not shown) may be formed over the grid structures (130a, 130b) and the color filters 140, and a microlens (not shown) may be formed over the overcoating layer.

In a situation where the light absorption layer 170 is formed at the outside of the dummy pixel region 100D as shown in FIG. 2, when the sacrificial layer 132’ is formed as in FIG. 5, the sacrificial layer 132’ in a region adjacent to the light absorption layer 170 may be formed higher than another sacrificial layer 132’ located more inward than the sacrificial layer 132’. For example, in the dummy pixel region 100D, the sacrificial layer pattern 132” may have a constant width but gradually increase in height in a direction from the center point to the edge region of the pixel region 100.

In a situation where the insulation layers (156, 157, 158) are formed as shown in FIG. 7, even if there is a height difference in the sacrificial layer pattern 132”, the sizes of the regions defined by the sacrificial layer pattern 132” and the insulation layer 134’ are equal to each other as a whole, so that the insulation layers (156, 157, 158) may be formed flat as a whole. That is, the distance between the top surface of the sacrificial layer pattern 132” and the DSA pattern becomes shorter in the direction closer to the edge region in the dummy pixel region 100D.

In such a state, when openings 164 are formed using the DSA pattern, the size of the openings 164 formed in the sacrificial layer pattern 132” formed to have a high height may be relatively larger than the size of the openings 164 formed in the sacrificial layer pattern 132” formed to have a low height. In addition, when the size of the openings 164 becomes larger, adjacent openings may be connected to each other to form a larger opening. That is, the first holes 168 formed in the edge region of the dummy pixel region 100D may be formed relatively large.

In such a state, when the second capping layer 136 is formed as shown in FIG. 12, the first holes 168 may not be completely filled in the grid structure 130b of the edge region, and some of the first holes 168 may be opened.

In this case, when the color filters and the overcoating layer are formed in a subsequent process, the color filter material and the overcoating material may penetrate into the air layer 132 through the unfilled holes. In some cases, the color filter material and the overcoating material may penetrate into the effective pixel region 100E.

However, as in the present embodiment, when the grid isolation region 130i is formed such that the grid structure (i.e., the second grid structure 130b) of the edge region and another grid structure (i.e., the first grid structure 130a) located more inward than the second grid structure are isolated from each other by the grid isolation region 130i, even if foreign substances (e.g., color filter materials or overcoating materials) are permeated into the air layer of the second grid structure 130b, it is possible to prevent the foreign substances from penetrating into the air layer of the first grid structure 130a.

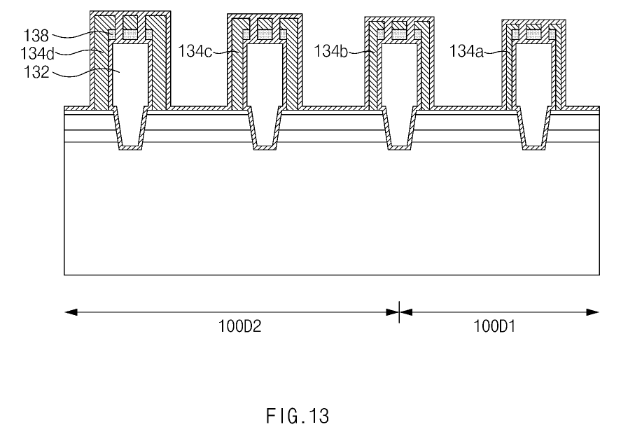

FIG. 13 is a cross-sectional view illustrating an example of the grid structure based on some embodiments of the disclosed technology.

Referring to FIG. 13, the second grid structure 130b formed in the second dummy pixel region 100D2 may be configured such that the capping layer surrounding the air layer 132 gradually increases in thickness in the direction closer to the edge region. For example, each of the first capping layer (134a~134d) of the second grid structure 130b may gradually become thicker in the direction closer to the edge region thereof.

Although FIG. 13 has disclosed an example case in which the thickness of each of the first capping layers (134a~134d) adjacent to each other continuously increases for convenience of description, other implementations are also possible, and it should be noted that the second grid structure 130b may also be formed in a shape in which the thickness of each of the first capping layers gradually increases in a predetermined range. For example, the second dummy pixel region 100D2 may be divided into a plurality of regions based on the distance from the grid isolation region 130i to the edge region, and the thickness of the first capping layer may gradually increase as the regions are located closer to the edge region, but the first capping layer may have the same thickness within the same region. The first capping layer 134 in the first grid structure 130a may have the same thickness as a whole. For example, the first grid structure 130a may be formed in such a way that the thicknesses of the capping layers are equal to with each other as a whole.

As described above, when the thickness of the first capping layer (134a~134d) in the second dummy pixel region 100D2 gradually increases in the direction closer to the edge region, the size of the region defined by the second grid structure 130b becomes smaller in the direction closer to the edge region. In such a case, when the insulation layer 156 is formed as shown in FIG. 7, the thickness of the insulation layer 156 may also gradually increase in the direction closer to the edge region. In this way, when the height of the sacrificial layer pattern 132” gradually increases in the direction closer to the edge region, the thickness of the insulation layer 156 also increases in the direction closer to the edge region, so that the distance between the DSA pattern and the top surface of the sacrificial layer pattern 132” may become similar overall.

In such a state, when holes 164 are formed using the DSA pattern, the size of the holes 164 may be formed uniformly throughout. Accordingly, when the second capping layer 136 is formed, the first holes 168 in the edge region may also be well filled.

Therefore, as the grid isolation region 130i is formed in the dummy pixel region 100D, the capping layer of the grid structure 130 in the second dummy pixel region 100D2 becomes thicker in the direction closer to the edge region, so that the resultant grid structure 130 can more effectively prevent foreign substances from penetrating into the air layer of the effective pixel region 100E.

If necessary, the capping layer of the grid structure 130 in the dummy pixel region 100D in which the grid isolation region 130i is not formed may be formed to become thicker in the direction closer to the edge region.

As is apparent from the above description, the image sensing device based on some embodiments of the disclosed technology may prevent foreign substances from penetrating into the air layer of the effective pixel region within the grid structure including the air layer.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device, comprising:
a semiconductor substrate;
an image pixel region supported by the semiconductor substrate;
a first dummy pixel region supported by the semiconductor substrate and located outside the image pixel region;
a second dummy pixel region supported by the semiconductor substrate and located outside the first dummy pixel region and the image pixel region;
a plurality of color filters disposed over the semiconductor substrate to correspond to pixels of the image pixel region, pixels of the first dummy pixel region and pixels of the second dummy pixel region; and
a grid structure disposed between the plurality of color filters,
wherein the grid structure includes:
a first grid structure disposed within the image pixel region and the first dummy pixel region and continuously connected in a first direction and a second direction intersecting the first direction; and
a second grid structure disposed within the second dummy pixel region and continuously connected in the first direction and the second direction,
wherein
the first grid structure and the second grid structure are isolated from each other.

2. The image sensing device according to claim 1, further comprising:
a pixel isolation structure supported by the semiconductor substrate and located between pixels of the pixel region, the first dummy pixel region and the second dummy pixel region to isolate adjacent pixels, and
wherein the grid structure is configured such that a bottom surface of the grid structure extends to the pixel isolation structure.

3. The image sensing device according to claim 1, wherein each of the first grid structure and the second grid structure includes:
an air layer; and
a capping layer surrounding the air layer.

4. The image sensing device according to claim 3, wherein:
the capping layer gradually becomes thicker in a direction closer to an edge region of the second dummy pixel region.

5. The image sensing device according to claim 3, wherein the capping layer includes:
a first capping layer surrounding the air layer and including a plurality of holes; and
a second capping layer surrounding the first capping layer and filling the plurality of holes.

6. The image sensing device according to claim 5, wherein:
the first capping layer gradually becomes thicker in a direction closer to an edge region of the second dummy pixel region.

7. The image sensing device according to claim 5, wherein:
the first capping layer is disposed in the second capping layer.

8. The image sensing device according to claim 5, wherein the second capping layer includes:
an inner capping layer covering an inner surface of the first capping layer;
an outer capping layer covering an outer surface of the first capping layer; and
a buried capping layer connected to the inner capping layer and the outer capping layer and filling the plurality of holes.

9. The image sensing device according to claim 5, wherein:
the first capping layer and the second capping layer include a same material layer.

10. The image sensing device according to claim 9, wherein:
each of the first capping layer and the second capping layer includes an ultra-low-temperature-oxide (ULTO) layer.

11. The image sensing device according to claim 5, wherein:
the first capping layer and the second capping layer include different material layers.

12. The image sensing device according to claim 11, wherein:
the first capping layer includes an ultra-low-temperature oxide (ULTO) layer; and
the second capping layer includes at least one of an aluminum oxide layer (Al₂O₃), a hafnium oxide layer (HfO₂), or a silicon nitride layer (SiN).

13. The image sensing device according to claim 8, wherein each of the first grid structure and the second grid structure further includes:
a support layer disposed between the first capping layer and the inner capping layer and including a plurality of holes.

14. An image sensing device comprising:
a semiconductor substrate including a first region and a second region surrounding the first region;
a plurality of color filters disposed over the semiconductor substrate; and
at least one grid structure disposed between adjacent color filters of the plurality of color filters,
wherein
the at least one grid structure includes a first grid structure in the first region and a second grid structure in the second region, and
the first grid structure of the first region and the second grid structure of the second region are disconnected from each other.

15. The image sensing device according to claim 14, wherein the at least one grid structure includes:
an air layer;
a first capping layer surrounding the air layer and including a plurality of holes; and
a second capping layer surrounding the first capping layer and filling the plurality of holes.

16. The image sensing device according to claim 15, wherein:
the grid structure is configured such that the first capping layer gradually becomes thicker in a direction closer to an edge region of the second region.

17. An image sensing device comprising:
a semiconductor substrate including a first region and a second region surrounding the first region;
a plurality of color filters disposed over the semiconductor substrate; and
a grid structure disposed between the plurality of color filters and configured to include an air layer and a capping layer surrounding the air layer,
wherein
the grid structure is configured such that a layer thickness of the capping layer gradually becomes thicker in a direction closer to an edge region of the second region.

18. The image sensing device according to claim 17, wherein the capping layer includes:
a first capping layer surrounding the air layer and including a plurality of holes; and
a second capping layer surrounding the first capping layer and filling the plurality of holes.

19. The image sensing device according to claim 18, wherein:
the first capping layer gradually becomes thicker in a direction closer to the edge region in a continuous manner or in units of a predetermined range.

20. The image sensing device according to claim 17, further comprising:
a pixel isolation structure located in the first region and the second region to isolate adjacent pixels, and
wherein the grid structure is configured such that a bottom surface of the grid structure extends to the pixel isolation structure.
